(19) United States
(12) Patent Application Publication
(10) Pub. No.: US 2008/0156460 A1
(43) Pub. Date: Jul. 3, 2008

(54) THERMAL MODULE

(75) Inventors: CHING-BAI HWANG, Tu-Cheng (TW); JIE ZHANG, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Tu-Cheng (TW)

(21) Appl. No.: 11/759,049

(22) Filed: Jun. 6, 2007

(30) Foreign Application Priority Data
Dec. 27, 2006 (CN) 200610157763.2

(51) Int. Cl. H05K 7/20

(52) U.S. Cl. 165/80.3; 361/700; 165/104.33

(57) ABSTRACT

A thermal module (200) includes a centrifugal blower (20) including a housing (21) and a rotor (22) rotatably deposed in the housing, a fin assembly (30) including a plurality of fins (31) disposed at an air outlet (24) of the centrifugal blower and a heat pipe (40) including a condenser section (42) thermally connecting with the fin assembly. The fins of the fin assembly are stacked along a direction parallel to a rotation axis (A) of the rotor; the heat pipe is flattened and forms a bend portion (43) at a free end of the condenser section thereof; the fins of the fin assembly define substantially rectangular-shaped receiving holes (314) therein; the condenser section of the heat pipe is thermally and physically attached to an outmost fin of the fin assembly and the bend portion is received in the receiving holes of the fins of the fin assembly.

### BACKGROUND OF THE INVENTION

1. Field of the Invention

The present invention relates generally to a thermal module, and more particularly to a thermal module for dissipating heat generated by electronic components in a portable electronic device, for example.

2. Description of Related Art

Following the increase in computer processing power that has been seen in recent years, greater emphasis is now being laid on increasing the efficiency and effectiveness of thermal module. Referring to FIGS. 4A and 4B, a conventional thermal module of a notebook computer includes a heat-conducting plate 110, a heat pipe 120, a fan 130 and a fin assembly 140. The heat-conducting plate 110 collects the heat energy generated by the central processing unit (CPU) of the notebook computer and the heat pipe 120 transfers the heat energy to the fin assembly 140. Then, the fan 130 blows on the fin assembly 140 to carry the heat energy out of the notebook computer.

Arrows 150 in FIG. 4B show airflow directions inside the fan 130. Arrows 160 show airflow directions outside the fin assembly 140 and a length of each of the arrows 160 indicates airflow volume at a corresponding location. As shown in FIG. 4B, airflow directions indicated by arrows 150 are continuously changed from a right angle to an acute angle relative to the fins of the fin assembly 140 as the airflow caused by the rotating fan 130 flows from upstream to downstream across an air outlet of the fan 130. When the airflows contact the fin assembly 140, the airflow direction is changed by the fin assembly 140. Therefore, angles between the airflows and the fins of the fin assembly 140 vary in different positions relative to the fan 130 and the fin assembly 140. When the angle is larger, the exhausting volume is lower and a noise caused due to turbulence in the fin assembly 140 is more serious, and the impaction between the airflow and the fin assembly 140 is more serious. This may cause a loss in kinetic energy of the airflow. Thus, speed of the airflow flowing through the fin assembly 140 may be reduced. The heat dissipation efficiency of the thermal module will thereby be further reduced. Therefore, there is a need to provide a quieter thermal module with better heat dissipation efficiency.

### SUMMARY OF THE INVENTION

The present invention relates to a thermal module for dissipating heat from a heat-generating electronic component in a portable electronic device, for example. According to a preferred embodiment of the present invention, the thermal module includes a centrifugal blower, a heat pipe including a condenser section and a fin assembly including a plurality of fins. The centrifugal blower includes a housing and a rotor rotatably disposed in the housing. The fins of the fin assembly are arranged at an air outlet of the centrifugal blower and stacked horizontally together along a direction parallel to a rotation axis of the rotor of the centrifugal blower. The heat pipe is flattened and forms a bend portion at a free end of the condenser section thereof. The fins of the fin assembly define substantially rectangular-shaped receiving holes therein, the condenser section of the heat pipe is thermally and physically attached to an outmost fin of the fin assembly and the bend portion of the condenser section of the heat pipe is received in the receiving holes of the fins of the fin assembly. By the arrangement that the fins are mounted horizontally at the outlet of the fan, the airflow generated by the fan can more smoothly flow through the fins with lower noise and take more heat from the fins. Furthermore, by the bend portion of the condenser section of the heat pipe fitted through the fins, heat of the heat-generating electronic component can be more effectively transferred to the fin assembly via the heat pipe.

Other advantages and novel features of the present invention will become more apparent from the following detailed description of preferred embodiments when taken in conjunction with the accompanying drawings, in which:

### BRIEF DESCRIPTION OF THE DRAWINGS

FIG. 1 is an exploded, isometric view of a thermal module according to a preferred embodiment of the present invention;

FIG. 2 is an assembled view of the thermal module of FIG. 1;

FIG. 3 is an assembled view of a thermal module according to another preferred embodiment of the present invention;

FIG. 4A is a conventional thermal module of a notebook computer; and

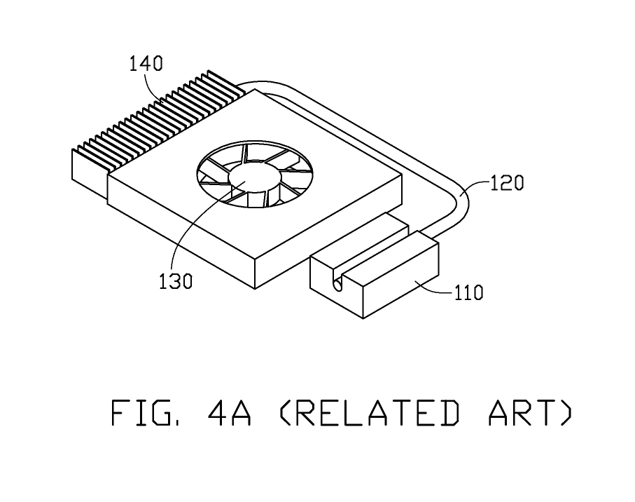

FIG. 4B shows air flow field of the thermal module of FIG. 4A.

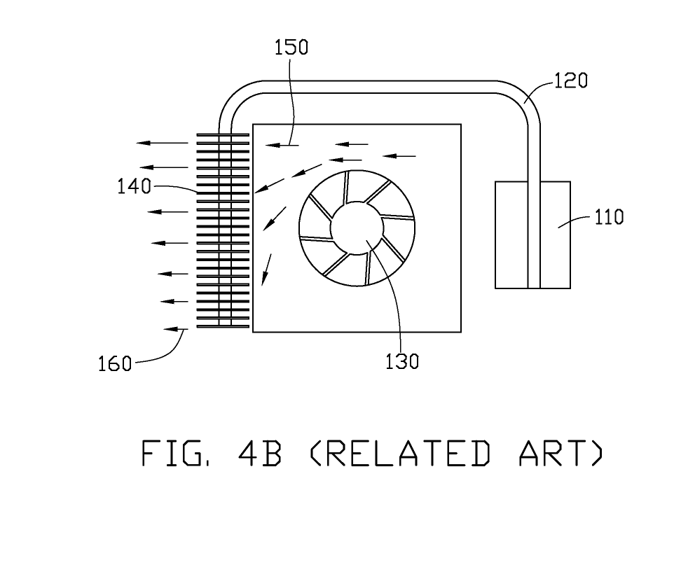

### DETAILED DESCRIPTION OF THE INVENTION

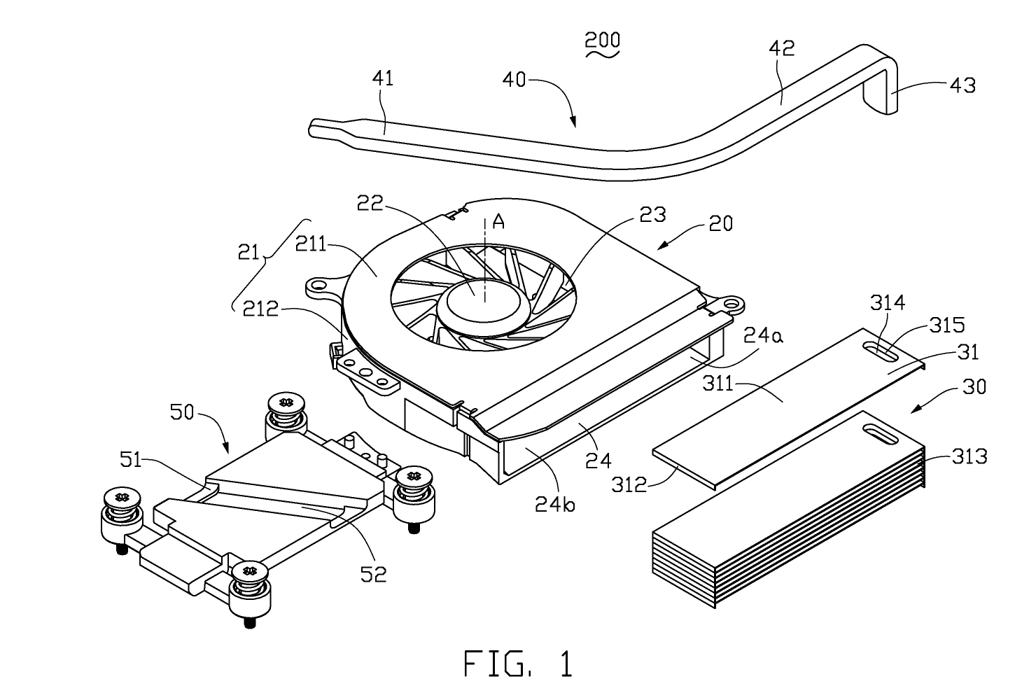

Referring to FIG. 1, a thermal module 200 according to a preferred embodiment of the present invention is shown. The thermal module 200 is used for dissipating heat generated by a heat-generating electronic component (not shown) of a portable electronic device such as a notebook computer. The thermal module 200 includes a centrifugal blower 20, a fin assembly 30, a heat pipe 40 and a heat-conducting plate 50. The heat-conducting plate 50 thermally connects with the electronic component (not shown) under the heat-conducting plate 50 and absorbs heat energy therefrom; the heat pipe 40 transfers the heat energy to the fin assembly 30 and then the centrifugal blower 20 blows on the fin assembly 30 to carry the heat energy out of the notebook computer.

The centrifugal blower 20 includes a housing 21 and a rotor 22 accommodated in an inner space of the housing 21. The rotor 22 rotates along a clockwise direction around a rotation axis A thereof. The housing 21 includes a top wall 211 and a sidewall 212 perpendicular to the top wall 211. The top wall 211 defines a circular air inlet 23 therein for the air outside flowing into the centrifugal blower 20. The sidewall 212 defines a linear-shaped air outlet 24 at a lateral side thereof. The air outlet 24 has a front side 24a in an upstream section thereof and a rear side 24b in a downstream section thereof. During operation of the centrifugal blower 20, airflow caused by the centrifugal blower 20 first flows towards the front side 24a of the air outlet 24 and then towards the rear side 24b thereof, and then the airflow leaves the air outlet 24 and blows on the fin assembly 30 to take the heat energy away therefrom. The airflow adjacent to the front side 24a of the air outlet 24 has a larger air pressure and flow rate than that of the airflow adjacent to the rear side 24b of the air outlet 24.

The fin assembly 30 including a plurality of fins 31 is disposed at the air outlet 24 of the centrifugal blower 20. The fins 31 are stacked horizontally one above another along a direction parallel to the rotation axis A of the rotor 22. Each of the fins 31 includes a rectangular-shaped main body 311, and two flanges 312 perpendicularly and downwardly extending from two opposite ends of the main body 311, respectively. The flanges 312 of an upper fin 31 abut against the main body 311 of a lower fin 31 so as to form an air passage 313 between the two adjacent fins 31, and the fins 31 of fin assembly 30 are combined together by soldering or other means such as by engaging structures formed between adjacent fins 31. For example, such engaging structures include, without limitation, holes formed in one fin 31 and engaging hooks formed on an adjacent fin 31 to engage in the holes of the one fin 31. Airflow caused by the centrifugal blower 20 flows through the air passages 313 between the fins 31 and exchanges heat energy with the fins 31 of the fin assembly 30. The main body 311 of each fin 31 defines a substantially rectangular-shaped receiving hole 314 at an end of the main body 311 corresponding to the front side 24a of the air outlet 24 for receiving a portion of the heat pipe 40. In addition, a collar 315 extends downwards from a periphery of the receiving hole 314 to increase the contact area between the fins 31 and the heat pipe 40.

The heat pipe 40 is flattened so as to increase the contact area with the heat-conducting plate 50 and the fins 31 of the fin assembly 30. The heat pipe 40 includes an evaporator section 41 and a condenser section 42. The evaporator section 41 thermally contacts with the heat-conducting plate 50 to absorb heat energy therefrom, whilst the condenser section 42 is thermally and physically attached to a top surface of an uppermost fin 31 of the fin assembly 30 so as to transfer the heat energy to the fin assembly 30. A free end of the condenser section 42 is perpendicularly and downwardly bent to form a bend portion 43. The bend portion 43 is received in the receiving holes 314 of the fins 31 and a length of the bend portion 43 substantially equals to a height of the fin assembly 30.

The heat-conducting plate 50 is substantially rectangular in profile, and is made of material having good thermal conductivity such as copper or aluminum. In this embodiment, the heat-conducting plate 50 is made of copper or copper alloy. The heat-conducting plate 50 defines a groove 51 along a diagonal line thereof for fittingly receiving the evaporator section 41 of the heat pipe 40. The heat-conducting plate 50 defines a through hole 52 at a middle portion of the groove 51, so that the evaporator section 41 of the heat pipe 40 can directly contact with the electronic component and absorb heat energy therefrom.

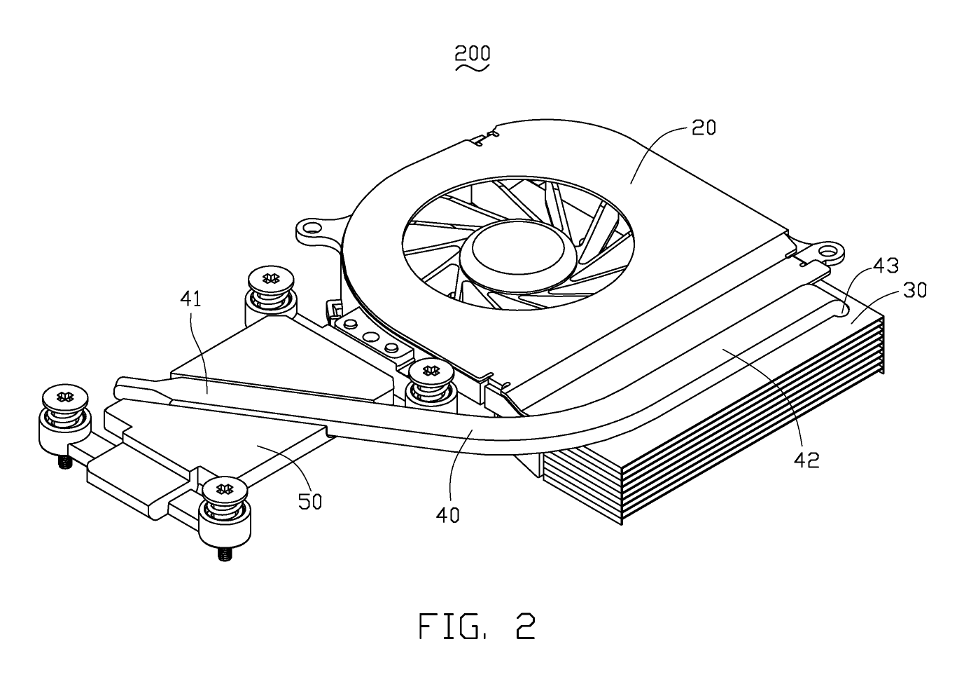

Referring to FIG. 2, in assembly, the fin assembly 30 is arranged at the air outlet 24 of the centrifugal blower 20. The evaporator section 41 of the heat pipe 40 is received in the groove 51 of the heat-conducting plate 50. The evaporator section 41 of the heat pipe 40 and the heat-conducting plate 50 are combined together by soldering. When mounting to the electronic component, a bottom of the evaporator section 41 of the heat pipe 40 is applied with a layer of thermal grease so as to increase the heat conducting efficiency between the electronic component and the evaporator section 41 of the heat pipe 40. The condenser section 42 of the heat pipe 40 has two opposite flat surfaces, i.e., top and bottom surfaces, and the bottom flat surface of the condenser section 42 is thermally and physically attached to the top surface of the uppermost fin 31 of the fin assembly 30 by soldering. The bend portion 43 of the heat pipe 40 is received in the receiving holes 314 of the fins 31 of the fin assembly 30. Thermal medium such as soldering tin is filled between the collars 315 of the receiving holes 314 and outer walls of the bend portion 43 so as to make the fins 31 of the fin assembly 30 thermally and mechanically combine with the bend portion 43 of the heat pipe 40.

In the present thermal module 200, the fins 31 of the fin assembly 30 are arranged at the air outlet 24 of the centrifugal blower 20 and stacked horizontally together along a direction that is parallel to the rotation axis A of the rotor 22 of the centrifugal blower 20, so that a flow direction of the airflow flowing towards the fin assembly 30 is parallel to each of the air passages 313 of the fin assembly 30. The airflow thereby smoothly and evenly flows through the fin assembly 30 without generating turbulence in the fins 31, which consequently reduces the noise caused by the turbulence in the fin assembly 30 and does not affect the flow speed of the airflow through the fin assembly 30. The condenser section 42 of the heat pipe 40 is thermally and physically attached to the top surface of the uppermost fin 31 of the fin assembly 30 and the bend portion 43 of the heat pipe 40 is received in the receiving holes 314 of the fins 31, thus greatly increasing the contact area between the condenser section 42 of the heat pipe 40 and the fins 31 of the fin assembly 30. The heat pipe 40 is flattened, which further increases the contact area with the topmost fin 31 of the fin assembly 30. Therefore, the heat exchanging efficiency between the heat pipe 40 and the fins 31 of the fin assembly 30 is enhanced, which increases the heat dissipating efficiency of the thermal module 200. The condenser section 42 of the heat pipe 40 is combined with the uppermost fin 31 of the fin assembly 30 by soldering, so that the heat conducting efficiency therebetween is further increased. The receiving hole 314 of the fin 31 is substantially rectangular-shaped corresponding to the shape of the flattened heat pipe 40, thus preventing the bend portion 43 of the heat pipe 40 received in the receiving holes 314 from rotating relative to the fins 31. Therefore, it is convenient to fix the condenser section 42 of heat pipe 40 with the fins 31 of the fin assembly 30. In addition, the collar 315 extending downwards from the periphery of the receiving hole 314 further increases the contact area between the condenser section 42 of the heat pipe 40 and the fins 31 of the fin assembly 30.

In the present thermal module 200, the receiving holes 314 of the fins 31 are defined at an end of the fins 31 corresponding to the front side 24a of the air outlet 24. The heat pipe 40 transfers the heat energy to the fins 31 of the fin assembly 30; thus, a temperature of front portions of the fins 31 adjacent to the front side 24a of the air outlet 24 is higher than a temperature of rear portions of the fins 31 adjacent to the rear side 24b of the air outlet 24, whilst an airflow caused by the centrifugal blower 20 adjacent to the front side 24a of the air outlet 24 has a larger air pressure and flow rate than an airflow adjacent to the rear side 24b of the air outlet 24. That is, the temperature gradient of the fins 31 across the fin assembly 30 matches with the pressure drop of the airflow across the air outlet 24. Therefore, the utilization rate of the airflow generated by the centrifugal blower 20 is increased.

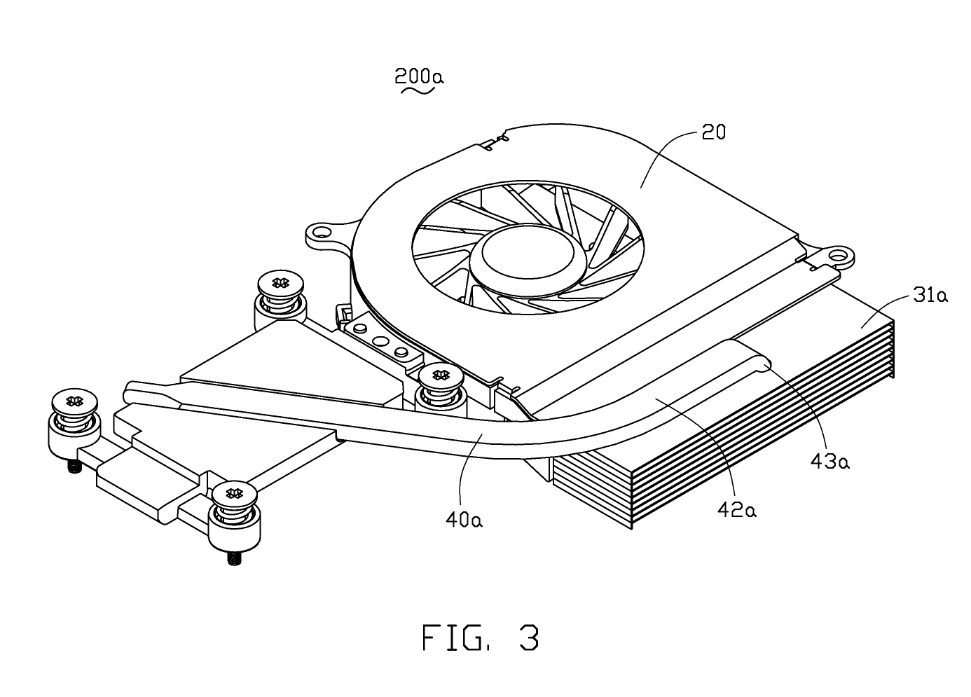

In the present thermal module 200, the receiving hole 314 of the fin 31 can also be defined at other portion of the fin 31. Referring to FIG. 3, a thermal module 200a according to another embodiment of the present invention is shown. In this embodiment of the thermal module 200a, receiving holes (not labeled) are defined substantially at a middle portion of the fins 31a of the fin assembly. A condenser section 42a of the heat pipe 40a is thermally and physically attached to a top surface of an uppermost fin 31a of the fin assembly and a bend portion 43a formed at a free end of the condenser section 42a is received in the receiving holes of the fins 31a. When the bend portion 43a of the heat pipe 40a exchanges heat energy with the fins 31a of the fin assembly, the heat energy can diffuse from center portion to both ends of the fins 31a of the fin assembly. Therefore, the heat exchanging efficiency between the heat pipe 40a and the fins 31a of the fin assembly is also acceptable. Indeed, the bend portion 43a of the heat pipe 40a can extend through the fins 31a at a selected position from the center portion to the front portion of each fin 31a that is adjacent to the front side 24a of the air outlet 24. Such arrangement can maintain a sufficiently large contact area between the condenser section 42a of the heat pipe 40a and the top surface of the uppermost fin 31a.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A thermal module comprising:
a centrifugal blower comprising a housing and a rotor rotatably disposed in the housing;
a fin assembly comprising a plurality of fins, the fin assembly disposed at an air outlet of the centrifugal blower; and
a heat pipe comprising a condenser section thermally connecting with the fin assembly;
wherein the fins of the fin assembly are stacked along a direction parallel to a rotation axis of the rotor, the heat pipe is flattened and forms a bend portion at a free end of the condenser section thereof, the fins of the fin assembly define substantially rectangular-shaped receiving holes therein, the condenser section of the heat pipe is thermally and physically attached to an outmost fin of the fin assembly and the bend portion of the heat pipe is received in the receiving holes of the fins of the fin assembly.

2. The thermal module as described in claim 1, wherein the air outlet has a front side and a rear side, airflow adjacent to the front side has larger air pressure and flow rate than airflow adjacent to the rear side, and the receiving holes are defined at end portions of the fins of the fin assembly corresponding to the front side of the air outlet.

3. The thermal module as described in claim 1, wherein the receiving holes are defines at middle portions of the fins of the fin assembly.

4. The thermal module as described in claim 1, wherein the condenser section of the heat pipe is thermally and physically attached to a top surface of an uppermost fin of the fin assembly.

5. The thermal module as described in claim 1, wherein the condenser section of the heat pipe and the outmost fin of the fin assembly are combined together by soldering.

6. The thermal module as described in claim 1, wherein a collar extends downwards from a periphery of the receiving hole of one fin towards an adjacent fin of the fin assembly.

7. The thermal module as described in claim 6, wherein the bend portion of the heat pipe and the collars of the fins are combined together by soldering.

8. The thermal module as described in claim 1 further comprising a heat-conducting plate for absorbing heat from an electronic component, wherein the heat pipe further comprises an evaporator section thermally connecting with the heat-conducting plate.

9. The thermal module as described in claim 8, wherein the heat-conducting plate is substantially rectangular in profile and defines a groove along a diagonal line thereof, the evaporator section being received in the groove.

10. The thermal module as described in claim 9, wherein the heat-conducting plate defines a through hole at a middle portion of the groove.

11. A thermal module comprising:
a centrifugal blower comprising a housing and a rotor rotatably disposed in the housing;
a heat-conducting plate for absorbing heat energy generated by an electronic component;
a fin assembly comprising a plurality of fins, the fin assembly disposed at an air outlet of the centrifugal blower, the air outlet having a front side and a rear side, airflow adjacent to the front side having larger air pressure and flow rate than airflow adjacent to the rear side; and
a heat pipe comprising a evaporator section thermally connecting with the heat-conducting plate and a condenser section thermally connecting with the fin assembly;
wherein the fins of the fin assembly are stacked along a direction parallel to a rotation axis of the rotor, the heat pipe is flattened and forms a bend portion at a free end of the condenser section thereof, each of the fins defines a substantially rectangular-shaped receiving hole at a selected position from a center portion to an end portion of the each of the fins adjacent to the front side of the air outlet, and the bend portion is received in the receiving holes of the fins of the fin assembly.

12. The thermal module as described in claim 11, wherein the condenser section of the heat pipe is thermally and physically attach to a surface of an outmost fin of the fin assembly.

13. The thermal module as described in claim 11, wherein the bend portion extends through the end portion of the each of the fins that is adjacent to the front side of the air outlet.

14. A thermal module comprising:
a centrifugal blower comprising an outlet from which airflow generated by the blower leaves of the blower;
a fin assembly comprising a plurality of fins stacked one above another, the fin assembly disposed at the air outlet of the centrifugal blower; and
a heat pipe comprising an evaporator section adapted for receiving heat from a heat-generating electronic component and a condenser section thermally connecting with and extending alone one of the fins of the fin assembly to thereby dissipate the heat to the fin assembly;
wherein the condenser section has a free end portion thereof being bent and inserted through at least some of the fins.

15. The thermal module as described in claim 14, wherein the free end of the condenser section is inserted through the at least some of the fins at a position corresponding to a position of the outlet of the blower between a front side position and a middle position of the outlet, the airflow at the front side position having a larger flow rate than at other position.

16. The thermal module as described in claim 15, wherein the free end of the condenser section is inserted through the at least some of the fins at a position corresponding to the front side position of the outlet of the blower.

17. The thermal module as described in claim 15, wherein the free end of the condenser section is inserted through the at least some of the fins at a position corresponding to the middle position of the outlet of the blower.
